(19) United States
(12) Patent Application Publication
(10) Pub. No.: US 2007/0186139 A1
(43) Pub. Date: Aug. 9, 2007

(54) Interleaving method for low density parity check encoding

(76) Inventors: Ki-Hyun Kim, Seongnam-si (KR); Yoon-Woo Lee, Suwon-si (KR); Hyun-jung Kim, Suwon-si (KR)

Correspondence Address: STEIN, MCEWEN & BUI, LLP, 1400 EYE STREET, NW, SUITE 300, WASHINGTON, DC, 20005, US

(21) Appl. No.: 10/580,935

(22) PCT Filed: Nov. 25, 2004
(86) PCT No.: PCT/KR04/03061

§ 371 Date: Mar. 9, 2007

(30) Foreign Application Priority Data
Nov. 29, 2003 (KR) 10-2003-0086048

(51) Int. Cl. H03M 13/00

(52) U.S. Cl. 714/758

(57) ABSTRACT

An interleaving method for use in a low density parity check (LDPC) encoding process employed by a network across which data is transmitted and/or in a recording/reproducing apparatus when information is stored on a recording medium. The method includes generating more than one code word vector by generating parity information based on a parity check matrix, dividing the generated code word vector into interleaving units, each interleaving unit having a size that is based on bit lengths between 1s included in a row of the parity check matrix, and interleaving the more than one code word vector using the differently sized interleaving units.

### CROSS-REFERENCE TO RELATED APPLICATIONS

This application claims the benefit of PCT International Patent Application No. PCT/KR2004/003061, filed Nov. 25, 2004, and Korean Patent Application No. 2003-86048, filed Nov. 29, 2003, in the Korean Intellectual Property Office, the disclosures of which are incorporated herein by reference.

### BACKGROUND OF THE INVENTION

1. Field of the Invention

An aspect of the present invention relates to an interleaving method, and, more particularly, to an interleaving method of achieving a high error correction rate when burst errors are generated in an encoding process using a low density parity check (LDPC) matrix.

2. Description of the Related Art

A low density parity check (LDPC) encoding and decoding method refers to an error correction encoding and decoding technology used in a wireless communication field and an optical recording/reproducing field. The LDPC encoding method was initially suggested by Gallager in 1962. However, since manufacturing a decoder at that time was difficult, the Gallager LDPC encoding method was abandoned.

Recently, another LDPC method was re-proposed by Mackey. The Mackey LDPC encoding method includes a process of generating parity information using a parity check matrix. Here, most components of the parity check matrix are 0, and very sparse components of the parity check matrix are 1. The LDPC encoding method provides excellent error correction performance by repeatedly performing an encoding process using an adding/multiplying algorithm. For example, an irregular LDPC encoding process where the length of encoding language is 10⁶ and an encoding rate is ½ has a performance closer to the Shannon limit, better than that of a turbo encoding process.

The LDPC encoding process is divided into a regular LDPC encoding process and an irregular LDPC encoding process. In the regular LDPC encoding process, the number of components of “1” included in a parity check matrix used in encoding and decoding is the same in every row and in every column. Otherwise, the LDPC encoding process is irregular. In the regular LDPC encoding process, the number of “1s” included in each row and each column are referred to as a row weight and a column weight, respectively.

The LDPC encoding process may be represented as shown in Equation 1.
H·Cₑ=0 [Equation 1]

Here, H indicates a parity check matrix, 0 indicates a zero matrix, “.” indicates an XOR operation and a modular 2 operation, and Ce indicates a code word vector, that is, a column matrix indicating a code word to be encoded. The code word includes an x-bit message word x1, x2, . . . , xx and p-bit parity information p1, p2, . . . , pp.

The parity information p₁, p₂, . . . , pₚ is generated so that the message word x₁, x₂, . . . , xₓ satisfies Equation 1. That is, since a binary value of the message word to be coded among components of the parity check matrix H and matrix Cₑ is determined, parity information pᵢ (i=1, 2, . . . , p) can be determined using Equation 1.

A more detailed description of the LDPC encoding process is described in “Good Error Correction Codes Based on Very Sparse Matrices” (D. J. MacKay, IEEE Trans. on Information Theory, vol. 45, no. 2, pp. 399-431, 1999).

Interleaving technologies deal with burst errors. In a communication or storage medium system, when a signal passes through a channel, a burst error on a specific portion of the transmitted signal may be generated. The burst error is generated by an external cause of a transmission medium in the communication system and by a scratch of a storage medium in the storage medium system. Since the burst error is generated on a specific location of a transmitted bit stream, if information existing on the specific location has been dispersed on other positions and is relocated to the original location when a decoding process is performed in a receiving end, an error volume of the location where the burst error is generated may be reduced. The residual error may be restored using information of a zone where an error is not generated, for example, parity information.

The interleaving technologies may be applied to the LDPC encoding process. One of the interleaving technologies applied to the LDPC generates error correction blocks using a plurality of code word vectors generated by a parity check matrix, divides the error correction blocks into predetermined sized unit blocks, and interleaves the unit blocks. However, when a conventional interleaving method is applied as is, no information exists with respect to the size of interleaving unit to interleave more effectively. That is, when a conventional interleaving method is applied to an LDPC encoding process, the size of an interleaving unit effective for the burst error correction of the LDPC encoding process is unknown.

### SUMMARY OF THE INVENTION

An aspect of the present invention provides an interleaving method of increasing reliability of error correction by determining the size of an optimum interleaving unit when a low density parity check (LDPC) encoding process is performed.

According to an aspect of the present invention, there is provided an interleaving method for use in a low density parity check (LDPC) encoding process employed by a network including a communication channel across which data is transmitted and/or in a recording/reproducing apparatus when information is stored on a recording medium. The method includes generating more than one code word vector by generating parity information based on a parity check matrix, dividing the generated code word vector into interleaving units, each interleaving unit having a size that is based on bit lengths between 1 s included in a row of the parity check matrix, and interleaving the more than one code word vector using the differently sized interleaving units.

The dividing of the generated code word vector into the interleaving units comprises: extracting a maximum range bit length including only one 1 among all 1 s included in the row of the parity check matrix; and determining the size of the interleaving units based on the extracted bit lengths.

According to another aspect of the present invention, there is provided A method of determining a size of an interleaving unit in a low density parity check (LDPC) encoding process employed by a network including a communication channel across which data is transmitted and/or in a recording/reproducing apparatus when information is stored on a recording medium, the method comprising: extracting valid code word bits which represent cord word bits corresponding to 1 s in a row of a parity check matrix in a code word vector; extracting bit lengths between the valid code word bits in the code word vector; and determining the size of the interleaving unit based on the bit lengths between the valid code word bits.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram of an encoding process and decoding process in a communication and storage medium system;

FIG. 2 illustrates a correlation between a parity check matrix and a generated code word vector in a low density parity check (LDPC) encoding process;

FIG. 3 illustrates a correlation between a location of 1 in an LDPC encoded code word vector and the size of a burst error;

FIG. 4 illustrates code word vectors each having a different interleaving unit size;

FIG. 5 illustrates a conventional method of determining the size of an interleaving unit when an error correction limit is 1 bit;

FIG. 6 illustrates a case where a code word vector is changed when interleaving and de-interleaving processes are performed by applying an interleaving unit according to an embodiment of the present invention; and

FIG. 7 illustrates a correlation between the reliability of error correction and the size of an interleaving unit when an error correction limit is 1 bit.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

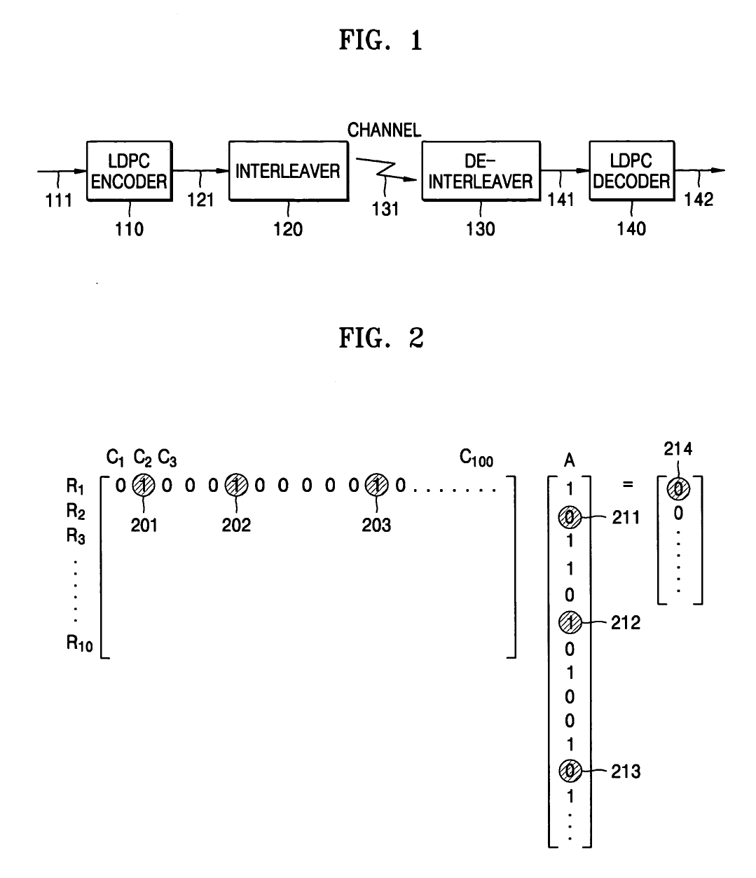

FIG. 1 is a schematic diagram of an encoding process and decoding process in a communication and storage medium system. As shown in FIG. 1, an LDPC encoder 110 receives an original message word 111 to be transmitted and generates a plurality of code word vectors 121 by LDPC encoding the original message word 111. Each code word vector 121 includes the message word 111 and parity information generated to satisfy Equation 1, as described above. An interleaver 120 receives the plurality of code word vectors 121 and generates an interleaved bit stream 131 by building an error correction block, by dividing the error correction block into a predetermined size of interleaving units, and by dispersing the interleaving units on suitable locations. In a communication system, the interleaved bit stream 131 is transmitted via a transmission medium such as air, and in a storage medium system, the interleaved bit stream 131 is transferred to a reproducing apparatus as the interleaved bit stream 131 was recorded on a storage medium.

At a receiving end or at a reproducing apparatus, a de-interleaver 130 receives the interleaved bit stream 131 and generates the code word vectors 141 by de-interleaving the interleaved bit stream 131. An LDPC decoder 140 receives the code word vectors 141 and generates the original message word 142 using an LDPC decoding algorithm.

FIG. 2 illustrates a correlation between a parity check matrix and a generated code word vector in an LDPC encoding process. As shown in FIG. 2, an LDPC encoding process is a process of generating parity information in a code word vector A so that a result of an XOR operation and a modular operation of a parity check matrix H and the code word vector A is a zero matrix. To know the parity information P₁, P₂, . . . existing in one code word vector, as many functions as the number of rows of the parity check matrix H are generated. The LDPC encoding process is a process of obtaining the parity information p₁, P₂, . . . by solving the functions. In the embodiment of FIG. 2, since the number of rows of the parity check matrix H is 10, 10 functions are generated.

Since the 10 functions are generated by the XOR and modular operations of the rows of the parity check matrix H and the code word vector A, only 1s in the rows of the parity check matrix H influence the generation of the functions. Therefore, only 1s, included in each row R₁, R₂, . . . of the parity check matrix H, influence the encoding process. Similarly, components equal to 0 included in each row R₁, R₂, . . . of the parity check matrix H do not influence a result of the encoding process.

As shown in FIG. 2, shaded components 201, 202, and 203 in a row R₁ of the parity check matrix H indicate the 1s, and shaded components 211, 212, and 213 in the code word vector A indicate components XOR and are modularly operated with the components 201, 202, and 203 of the parity check matrix H. In other words, the other components (non-shaded components in the code word vector A of FIG. 2) except the components 211, 212, and 213 in the code word vector A do not influence the LDPC encoding process.

An LDPC decoding algorithm is a process of generating the original code word vector A from a received code word vector A′. All currently used decoding algorithms use Equation 1 for the encoding process. That is, a decoding process is performed based on locations of “1s” existing in rows of a parity check matrix. This means that the code word bits 211, 212, and 213 corresponding to these locations in the code word vector A are decoded using the same decoding algorithm as in the decoding process.

An interleaving process is a process of dividing all code word vectors A, B, C, . . . into interleaving units of predetermined sizes and placing the interleaving units on different locations according to a predetermined rule. In the interleaving process, determining the size of an interleaving unit influences a reliability of error correction when a burst error is generated.

If the code word vectors are transmitted through a transmission channel or recorded on a storage medium using a maximum interleaving unit, that is, sequentially without the interleaving process, since all code word bits placed on a location where a burst error is generated belong to the same code word vector, a problem that a specific code word vector cannot be decoded may be generated. Also, if the size of interleaving unit is too small, complex problems may be generated during the de-interleaving process. In addition, realizing a small sized interleaving unit is relatively difficult due to a limit according to the size of error correction block. Therefore, determining an optimum size of an interleaving unit is important in achieving a high reliability of error correction.

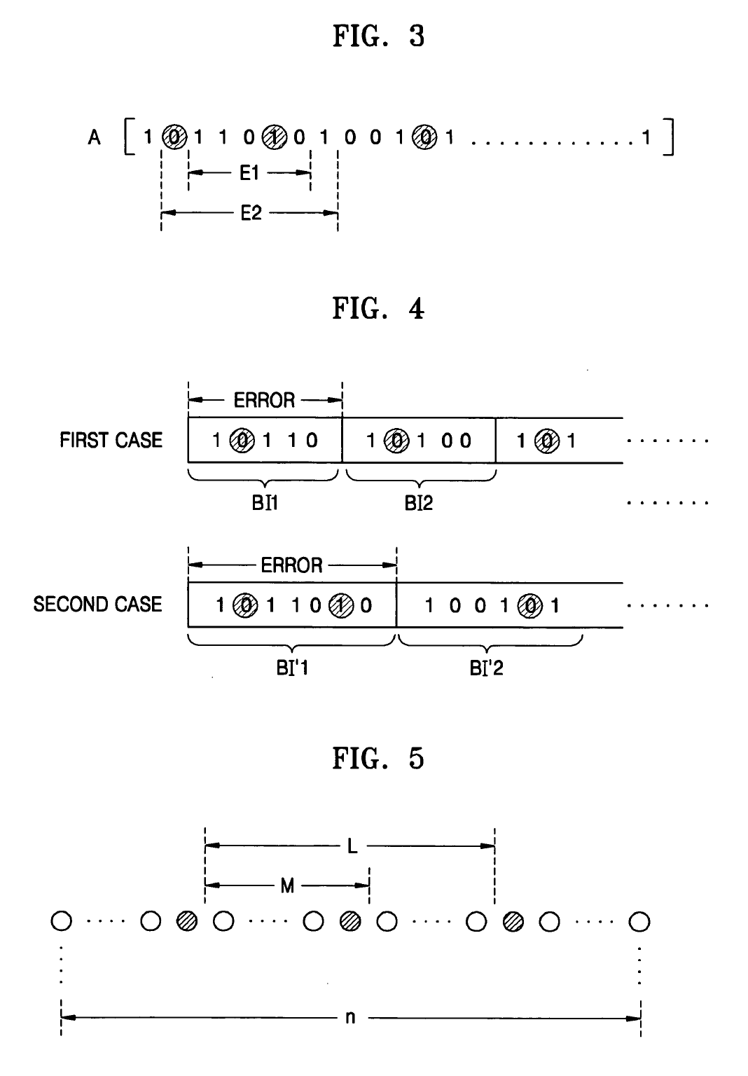

FIG. 3 illustrates a correlation between a location of 1 s in an LDPC encoded code word vector and the size of a burst error. As shown in FIG. 3, shaded code word bits, which are the code word bits 211, 212, and 213 and which correspond to locations in which components of the parity check matrix are “1” in the code word vector of FIG. 2, are defined as valid code word bits. If a burst error E1 is generated, the code word bits that are distorted by the burst error E1 are a third bit through a seventh bit, as shown. The code word bits distorted by the burst error E1 include one valid code word bit. If a burst error E2 is generated, the code word bits that are distorted by the burst error E2 are a second bit through a eighth bit. That is, the code word bits distorted by the burst error E2 include two valid code word bits, as shown.

The size of an interleaving unit is related to the number of valid code word bits influenced by a burst error in a code word vector. This will be described in detail with reference to FIGS. 4 and 5. FIG. 4 illustrates code word vectors each having a different interleaving unit size, and also illustrates a correlation between the size of an interleaving unit and the number of valid code word bits in a code word vector.

In a first case illustrated by FIG. 4, the interleaving unit is 5 bits, and, in a second case, the interleaving unit is 7 bits. Here, an interleaving process is not yet performed. When interleaving units BI1, BI2, . . . are transmitted via a channel or recorded on a storage medium, since each interleaving unit BI1, BI2, . . . may be placed on a different location, that is, since the interleaving units BI1, BI2, . . . may be interleaved, the interleaving units BI1, BI2, . . . are not influenced by the same burst error. Therefore, even if a burst error that is larger than the interleaving unit is generated, only an interleaving unit having as many bits as a maximum size is influenced by the burst error in a code word vector. Also, it is assumed that an error correction limit is 1 bit.

In the first case, the interleaving unit BI1 includes one valid code word bit. It is assumed that a burst error is generated on a location where the interleaving unit BI1 is placed and the size of the burst error is 8 bits. Even if the size of burst error is 8 bits, since the interleaving units are influenced by the burst error after they are interleaved, the burst error influencing the interleaving unit BI1 cannot influence a de-interleaved interleaving unit BI2.

As described in FIG. 3, since only valid code word bits influence parity information in a code word vector when the LDPC encoding process is performed, and since the number of valid code word bits included in the interleaving unit BI1 is 1, the error generated on the code word vector A is a 1-bit error. Since the interleaving unit BI2 is not located near the interleaving unit BI1 in the channel or medium by the interleaving process, the error does not influence the interleaving unit BI2 although the size of the burst error is 8 bits, and the error may be corrected.

In the second case, an interleaving unit BI′1 includes two valid code word bits. As in the first case, it is assumed that a burst error is generated on a location where the interleaving unit BI′1 is placed and the size of the burst error is 8 bits as shown in FIG. 4. Unlike the first case, however, since the number of valid code word bits included in the interleaving unit BI′1 is 2, the error generated on the code word vector A is a 2-bit error, and the error cannot be corrected.

In FIG. 4, arrow marks indicate zones influenced by the same burst error with respect to the two interleaving units. Even if an 8-bit burst error is generated in the two cases, since the interleaving unit is 5 bits in the first case, only the 5 bits were influenced by the burst error, and since the interleaving unit is 7 bits in the second case, the 7 bits were influenced by the burst error. The residual 3 bits influenced by the burst error of the first case and the residual 1 bit influenced by the burst error of the second case will be placed in any one of code word vectors B, C, . . . Since the code word bits influenced by the burst error, which are placed in any one of code word vectors B, C, . . . , belong to different code word vectors, the code word bits are not related to the error correction of the code word vector.

In sum, the size of the interleaving unit should be determined so that each interleaving unit has valid code word bits within the error correction limit. In the embodiment of FIG. 4, since it is assumed that the error correction limit is 1 bit, each interleaving unit must have one or no valid code word bit.

FIG. 5 illustrates a conventional method of determining the size of an interleaving unit when an error correction limit is 1 bit. As shown in FIG. 5, horizontally arranged round dots indicate code word bits in a specific code word vector. Also, shaded round dots correspond to valid code word bits, n indicates a length of the specific code word vector, M indicates an average length between valid code word bits, and L indicates a maximum number of bits including only one valid code word bit.

As described above, to correct a burst error, interleaving units must be determined so that each interleaving unit has valid code word bits within the error correction limit. Accordingly, a maximum value of the size of interleaving unit permitted in FIG. 5 is L. The L value is different for every code word vector. Also, even in one code word vector, the L value is different according to how many valid code word bits the range of the L value includes.

However, if the average length M between valid code word bits is measurable, a value of the maximum length L, including only one valid code word bit, should be double the M value.

Therefore, the maximum size of an interleaving unit BImax and the M value have the following relationship:
BImax=L≈2M [Equation 2]

Here, BImax indicates the maximum size of interleaving unit, L indicates a maximum length of bits including only one valid code word bit, and M indicates an average length between valid code word bits.

The reason why the L value is not the same as the 2M value is because lengths between valid code word bits are different according to code word vectors and different for every code word bit even in the same code word vector. That is, lengths between 1 s in a parity check matrix may be different even if they are in the same row.

In particular, in the regular LDPC encoding process, the number of valid code word bits included in a code word vector is the same as a row weight Wr of a parity check matrix. Also, an average length between valid code word bits is the same as a value of double the length of the code word vector n divided by the row weight Wr of the parity check matrix. Therefore, in the regular LDPC encoding process, the maximum value of the size of interleaving unit BImax may be represented as shown in Equation 3.
BImax=L∓2M=2n/Wr [Equation 3]

Here, n indicates a length of a code word vector, and Wr indicates a row weight of a parity check matrix.

If the error correction limit is 2 bits instead of 1 bit, L=3M. If the error correction limit is 3 bits, L=4M. If the error correction limit is k bits, L=(k+1)M. Accordingly, Equation 3 is generalized as shown in Equation 4.
BImax=L=(k+1)M=(k+1)n/Wr [Equation 4]

Here, k indicates an error correction limit, n indicates a length of a code word vector, and Wr indicates a row weight.

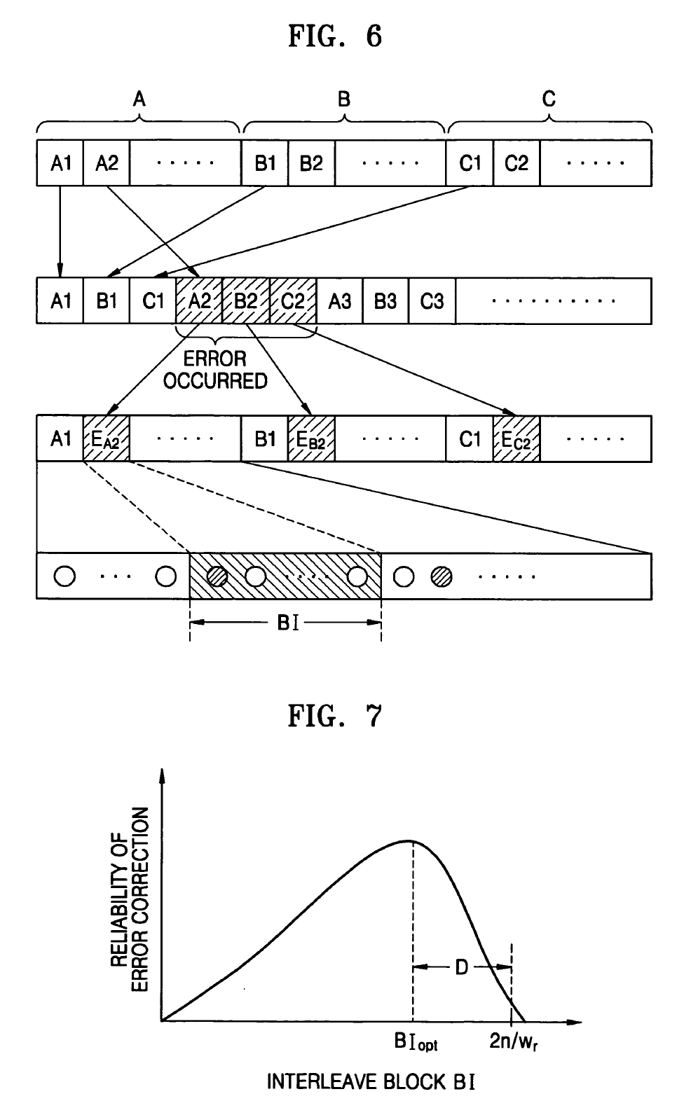

FIG. 6 illustrates a case where a code word vector is changed when interleaving and de-interleaving processes are performed by applying an interleaving unit according to an embodiment of the present invention.

A first drawing shows a bit stream including code word vectors A, B, C, . . . before the code word vectors are interleaved. The non-interleaved code word vectors A, B, C, . . . include interleaving units A1, A2, A3, . . . , B1, B2, B3, . . . , C1, C2, C3, . . . , respectively.

A second drawing shows a bit stream after the interleaving units A1, A2, A3, . . . , B1, B2, B3, . . . , C1, C2, C3, . . . are interleaved using a predetermined method. The interleaving method interleaves the bit stream by alternatively extracting interleaving units of code word vectors. The interleaved bit stream is transmitted via a communication channel or is stored in a storage medium.

A third drawing shows a bit stream after the bit stream is de-interleaved at a receiving end of the communication channel or in a reproducing apparatus. Here, it is assumed that a burst error is generated on a location where A2, B2, and C2 are placed. The burst error distorts the interleaving units A2, B2, and C2 to appear as interleaving units EA2, EB2, EC2. The distorted interleaving units EA2, EB2, EC2 are replaced in the original code word vectors by a de-interleaving process.

A fourth drawing shows an internal configuration of a code word vector A after a de-interleaving process. Here, the interleaving unit EA2 includes one valid code word bit. Therefore, the interleaving unit EA2 may be corrected by the other non-distorted interleaving units A1, A3, A4, . . . If the size of an interleaving unit is determined so that each interleaving unit includes two or more valid code word bits, since the interleaving unit EA2 includes two or more valid code word bits, the de-interleaved code word vector A also includes two or more valid code word bits. As a result, the error cannot be corrected.

FIG. 7 illustrates a correlation between the reliability of error correction and the size of an interleaving unit when an error correction limit is 1 bit.

As described above, according to aspects of the present invention, a maximum value, which an interleaving unit may have in a regular LDPC encoding process, is 2n/Wr. Therefore, a possible range of an interleaving unit BI is 1<BI<2n/Wr. The larger the n value, and the less the Wr value, the more the maximum value of the interleaving unit BI increases. FIG. 7 shows that the reliability of error correction dramatically drops near 2n/Wr.

That the reliability of error correction decreases at values smaller than the 2n/Wr value is due to the fact that a bit length between 1 s is not fixed in a parity check matrix. That is, since bit lengths between valid code word bits are not constant in all code word vectors or the same code word vector, a valid code word bit length having a value smaller than n/Wr, assumed as the average value, may exist. Therefore, the reliability of error correction may increase a little more by determining a smaller value than 2n/Wr as the interleaving unit size. Here, a difference D between the 2n/Wr value and the size of optimum interleaving unit BIₒₚₜ decreases as a distribution uniformity of 1 s included in a parity check matrix is higher and as a density of 1 s is lower, that is, as a row weight decreases.

An aspect of the present invention provides a method of optimally selecting a size of an interleaving unit. Optimally, this means extracting all L values and determining a smaller size than any L value as the size of the interleaving unit. However, it is also possible to regard a 2M value as the L value and then to determine a smaller value than the 2M value as the size of the interleaving unit. More simply, a smaller value than a 2n/Wr value may be regarded as the size of the interleaving unit. In the last two cases, even though the reliability of error correction decreases compared with the first case, the reliability increases compared with the conventional method, which does not account for a bit length between valid code word bits.

Although a few embodiments of the present invention have been shown and described, it would be appreciated by those skilled in the art that changes may be made in these embodiments without departing from the principles and spirit of the invention, the scope of which is defined in the claims and their equivalents.

1. An interleaving method for use in a low density parity check (LDPC) encoding process employed by a network including a communication channel across which data is transmitted and/or in a recording/reproducing apparatus when information is stored on a recording medium, the method comprising:
generating more than one code word vector by generating parity information based on a parity check matrix;
dividing the generated code word vector into interleaving units, each interleaving unit having a size that is based on bit lengths between 1 s included in a row of the parity check matrix; and
interleaving the more than one code word vector using the differently sized interleaving units.

2. The method of claim 1, wherein the dividing of the generated code word vector into the interleaving units comprises:
extracting a maximum range bit length including only one 1 among all 1 s included in the row of the parity check matrix; and
determining the size of the interleaving units based on the extracted bit lengths.

3. The method of claim 2, wherein the determining of the size of the interleaving units comprises determining an average value of the extracted bit lengths as the sizes of each of the interleaving units.

4. The method of claim 2, wherein the determining of the size of the interleaving units comprises determining a minimum value of the extracted bit lengths as the sizes of each of the interleaving units.

5. The method of claim 1, wherein the dividing the generated code word vector into interleaving units comprises:
extracting bit lengths between all 1 s existing in the row of the parity check matrix;
calculating an average value of the extracted bit lengths; and
determining a bit length corresponding to double the length of the calculated average value of the extracted bit lengths as the sizes of each of the interleaving units.

6. The method of claim 1, wherein the dividing of the generated code word vector into the interleaving units comprises:
determining the sizes of each of the interleaving units based on the length of the code word vector and the row weight of the parity check matrix; and
dividing the code word vector into the interleaving units having the determined sizes.

7. The method of claim 6, wherein the determining of the size of the interleaving units comprises determining a smaller value than a value corresponding to double the value of the length of the code word vector by the row weight as the sizes of each of the interleaving units.

8. A method of determining a size of an interleaving unit in a low density parity check (LDPC) encoding process employed by a network including a communication channel across which data is transmitted and/or in a recording/reproducing apparatus when information is stored on a recording medium, the method comprising:
extracting valid code word bits which represent code word bits corresponding to 1 s in a row of a parity check matrix in a code word vector;
extracting bit lengths between the valid code word bits in the code word vector; and
determining the size of the interleaving unit based on the bit lengths between the valid code word bits.

9. The method of claim 8, wherein the determining of the size of the interleaving unit comprises determining a smaller value than double the minimum value of the bit lengths between the valid code word bits as the size of the interleaving unit.

10. The method of claim 8, wherein the determining of the size of the interleaving unit comprises determining a smaller value than double the average value of the bit lengths between the valid code word bits as the size of the interleaving unit.

11. The method of claim 10, wherein the average value of the bit lengths between the valid code word bits is a value obtained by dividing the length of the code word vector by the row weight of the parity check matrix.

12. The method of claim 8, wherein the determining of the size of the interleaving unit comprises determining the size of the interleaving unit so that 1<BI<2n/Wr, where BI indicates the size of the interleaving unit, n indicates the length of the code word vector, and Wr indicates the row weight of the parity check matrix.

13. An interleaving method for use in a low density parity check (LDPC) encoding process employed by a network including a communication channel across which data is transmitted and/or in a recording/reproducing apparatus when information is stored on a recording medium, the method comprising:
generating more than one code word vector by generating parity information based on a structure of a parity check matrix corresponding to the code word vector;
dividing the generated code word vector into interleaving units by extracting bit lengths between all 1 s existing in the row of the parity check matrix, calculating an average value of the extracted bit lengths, and setting a bit length of each of the interleaving units to be 1<BI<2n/Wr, where BI indicates the size of the interleaving unit, n indicates the length of the code word vector, and Wr indicates a row weight of the parity check matrix; and
interleaving the more than one code word vector using the interleaving units at the set bit lengths.

14. The method according to claim 13, wherein a difference between BI and 2n/Wr decreases as a distribution uniformity of 1 s included in the parity check matrix increases and as a density of 1 s in the parity check matrix decreases.

15. A method of determining a size of an interleaving unit in a low density parity check (LDPC) encoding process employed by a network including a communication channel across which data is transmitted and/or in a recording/reproducing apparatus when information is stored on a recording medium, the method comprising:
extracting valid code word bits which represent cord word bits corresponding to a number of 1 s in a row of a parity check matrix in a code word vector;
extracting bit lengths between the valid code word bits in the code word vector; and
optimally setting the size of the interleaving unit to be 1<BI<2n/Wr, where BI indicates the size of the interleaving unit, n indicates the length of the code word vector, and Wr indicates a row weight of the parity check matrix.

16. The method according to claim 13, wherein a difference between BI and 2n/Wr decreases as a distribution uniformity of 1 s included in the parity check matrix increases and as a density of 1 s in the parity check matrix decreases.
